(19) United States
(12) Patent Application Publication
(10) Pub. No.: US 2006/0113460 A1
(43) Pub. Date: Jun. 1, 2006

(54) Image sensor with optimized wire routing

(76) Inventor: Hiok Nam Tay, Singapore (SG)

Correspondence Address: IRELL & MANELLA LLP, 840 NEWPORT CENTER DRIVE, SUITE 400, NEWPORT BEACH, CA, 92660, US

(21) Appl. No.: 11/267,653

(22) Filed: Nov. 3, 2005

Related U.S. Application Data
(60) Provisional application No. 60/625,554, filed on Nov. 5, 2004.

(51) Int. Cl. H01L 27/00

(52) U.S. Cl. 250/208.1; 348/308; 348/241

(57) ABSTRACT

An image sensor that has a pixel array with a plurality of pixels. Each pixel includes a photodiode. The sensor includes a row decoder and a light reader that are connected to the pixel array by a plurality of conductive traces. In the outer areas of the pixel array the locations of the traces is shifted to optimize the amount of light that impinges onto the photodiodes.

### REFERENCE TO CROSS RELATED APPLICATION

This application claims priority under 35 U.S.C §119(e) to provisional application No. 60/625,554, filed on Nov. 5, 2004.

### BACKGROUND OF THE INVENTION

1. Field of the Invention

The subject matter disclosed generally relates to the field of semiconductor image sensors.

2. Background Information

Photographic equipment such as digital cameras and digital camcorders may contain electronic image sensors that capture light for processing into still or video images, respectively. Electronic image sensors typically contain millions of light capturing elements such as photodiodes. The photodiodes are arranged in a two-dimensional pixel array.

It is generally desirable maximize the amount of light that impinges on the photodiode. Any loss of light reduces the amount of energy converted by the photodiode and degrades the quality of the picture. U.S. Pat. No. 6,005,619 issued to Fossum and U.S. Pat. No. 6,633,334 issued to Sakurai et al. disclose designs that shape the photodiode and/or surrounding transistors to maximize the amount of light directing impinging the photodiode. U.S. Pat. No. 6,137,100 issued to Fossum et al. discloses a concept for increasing the sensitivity of blue light by increasing the relative size of the blue color filter. U.S. Pat. No. 6,744,032, issued to Tay, discloses the use of a microlens to direct light into less sensitive pixels.

A image sensor typically has row decoder and light reader circuits that can select pixels so that data can be read from the array. Each pixel has a conductive trace that extends from the row decoder and another conductive trace that extends from the light reader. The traces carry signals that are used to select the pixels and read data.

FIG. 1 shows a cross-section of a pixel in an outer area of an electronic image sensor. The pixel includes a photodiode 2 that receives light 4 focused by a micro-lens 6. The micro-lens 6 is located on a transparent spacer 8 above a color filter 10. Also shown are the color filters 12 of adjacent pixels. Located between the filters and the photodiode 2 are a plurality of interconnect layers M1, M2 and M3. Some of the interconnect layers are connected by vias/contacts V1 and V2. The light 4 travels through the color filter 10 and onto the photo-diode 2. The photodiode 2 converts the light into electrical energy.

At the outer area of the pixel array the light 4 tends to come in at an angle. This is due to the way the camera lens focuses the light. In the outer area, the interconnect layers M1 and M2 obstruct some of the light from reaching the photo-diode 2. This results in inaccurate data and a poor quality picture. It would be desirable to provide an image sensor that minimizes the amount of light obstruction in all areas of the pixel array. To date, none of the prior art addresses the issue of light obstruction by the interconnect layers.

### BRIEF SUMMARY OF THE INVENTION

An image sensor with a plurality of conductive traces that connect a row decoder and/or a light reader of the sensor to a pixel array. The array contains a plurality of pixels, each pixel contains a photodiode. The conductive traces are arranged in a manner that minimizes light obstruction onto the photodiodes.

### BRIEF DESCRIPTION OF THE DRAWINGS

FIG. 1 is an illustration of an image sensor of the prior art;

FIG. 2 is a schematic of an image sensor;

FIG. 3 is an illustration of a pixel in an outer area of a pixel array;

FIG. 4 is an illustration of a pixel in an inner area of a pixel array.

FIG. 5 is an illustration of row decoder conductive traces of the image sensor;

FIG. 6 is an illustration of light reader conductive traces of the image sensor.

### DETAILED DESCRIPTION

Disclosed is an image sensor that has a pixel array with a plurality of pixels. Each pixel includes a photodiode. The sensor includes a row decoder and a light reader that are connected to the pixel array by a plurality of conductive traces. In the outer areas of the pixel array the locations of the traces is shifted to optimize the amount of light that impinges onto the photodiodes.

The entire image sensor is preferably constructed with CMOS fabrication processes and circuits. Although a CMOS image sensor is described, it is to be understood that the conductive trace routing schemes disclosed herein may be implemented in other types of image sensors such as CCD sensors.

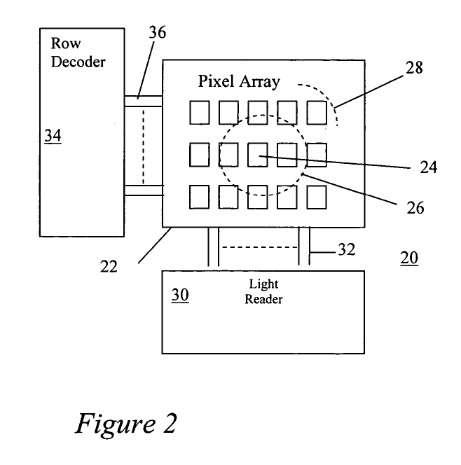

Referring to the drawings more particularly by reference numbers, FIG. 2 shows an image sensor 20. The image sensor 20 includes a pixel array 22 that contains a plurality of individual photo-detecting pixels 24. The pixels 24 are typically arranged in a two-dimensional array of rows and columns. The pixel array 22 has a center area 26 and an outer area 28.

The pixel array 22 is connected to a light reader circuit 30 by a plurality of conductive traces 32. The pixel array is connected to a row decoder 34 by conductive traces 36. The row decoder 34 can select an individual row of the pixel array 22. The light reader 30 can then read specific discrete columns within the selected row. Together, the row decoder 34 and light reader 30 allow for the reading of an individual pixel 24 in the array 22. The data read from the pixels 24 may be processed by other circuits such as a processor (not shown) to generate a visual display.

The image sensor 10 and other circuitry may be configured, structured and operated in the same, or similar to, the corresponding image sensors and image sensor systems disclosed in U.S. Pat. No. 6,795,117 is issued to Tay, which is hereby incorporated by reference.

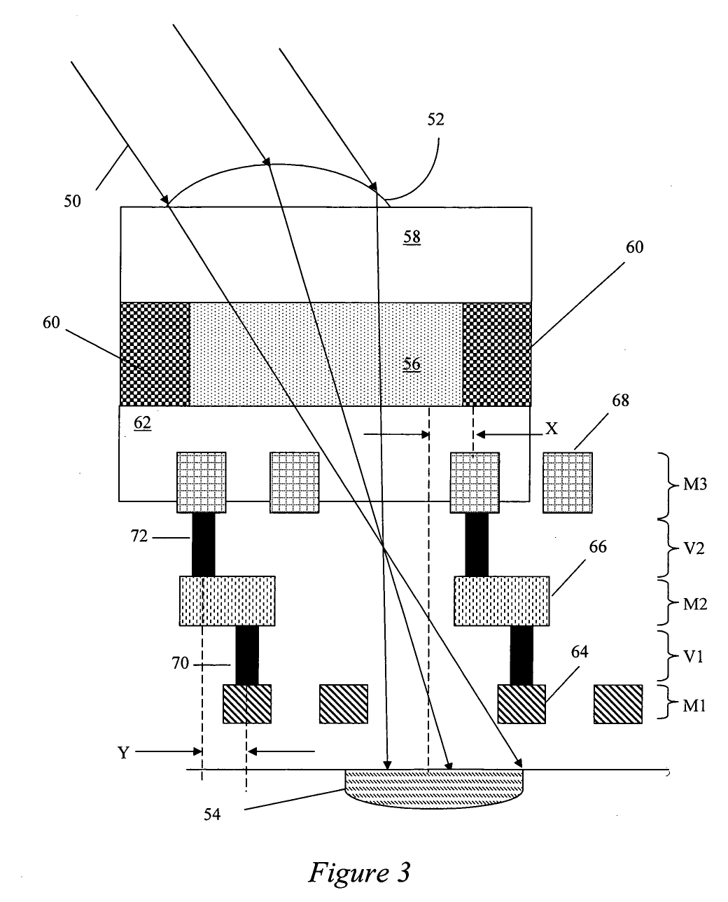

FIG. 3 shows a pixel located at an outer area of the pixel array. Light 50 is focused by a micro-lens 52 onto a photo-diode 54. The micro-lens 52 is separated from a color filter 56 by a transparent spacer layer 58. Also shown are color filters 60 for the adjacent pixels. The color filters 56 and 60 are adjacent to a planarization layer 62.

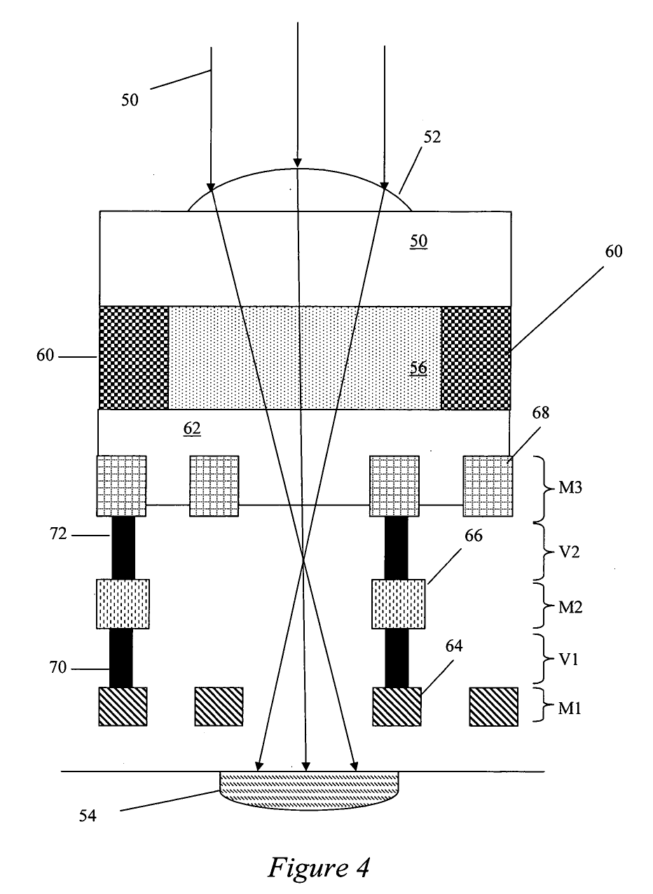

The sensor may have a first interconnect layer M1 64, a second interconnect layer M2 66 and a third interconnect layer M3 68. The interconnect layers M1, M2 and M3 may be interconnected by vias/contacts 70 and 72, respectively. The interconnect layers M1, M2 and M3 may include conductive traces that carry electrical current. FIG. 4 shows a pixel in an inner area of the pixel array.

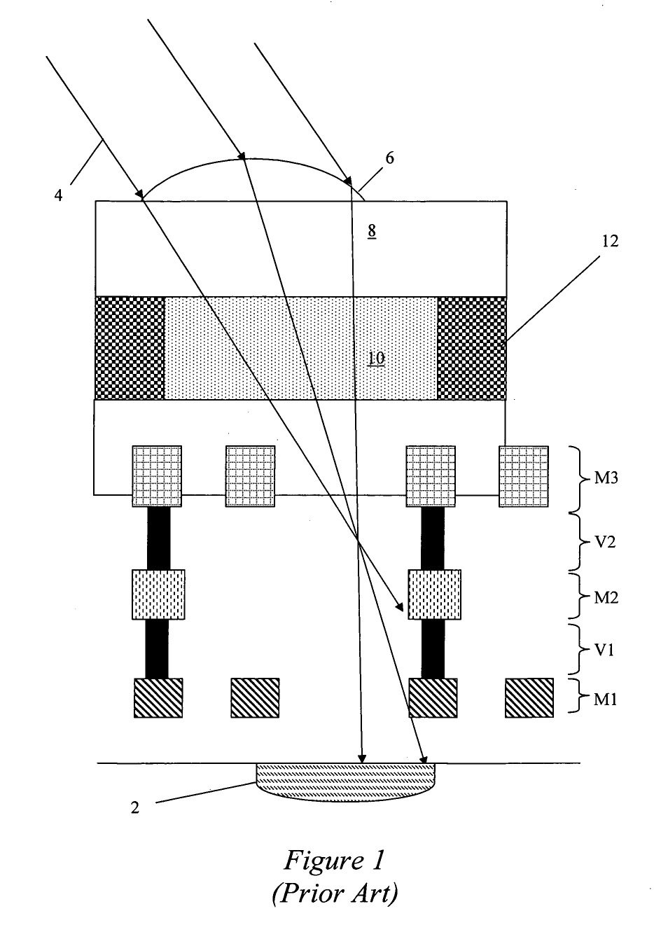

In the outer areas of the pixel array the conductive traces in the interconnect layers M1, M2 and M3 are shifted to allow the light to strike the photo-diode 54 unimpeded (Compare FIG. 3 with FIG. 1 showing the prior art).

The shift in the traces in layer M3 can be defined in terms of an offset relative to the photodiode 54 shown as dimension X. Dimension X for the pixels in the outer areas of the pixel array are different than the same dimension for the pixels in the inner areas of the array. The sensor thus has traces with a varying offset between the traces and the photodiodes of the pixels.

In the outer areas of the pixel array the vias V1 are offset from the vias V2. This offset can be defined by the dimension Y. This is to be distinguished from the pixels in the inner area of the pixel array where the vias V1 and V2 are aligned (see FIG. 4), or have an offset Y less than in the outer areas.

The offset vias allow the traces in the M3 layer to be shifted in the outer areas of the pixel array to optimize the amount of light that impinges onto the photodiode 54. In the outer area of the pixel array the conductors in the M2 layer are made longer to allow for the offset in the vias V1 and V2. Thus the image sensor has conductors that vary in length between at least two pixels.

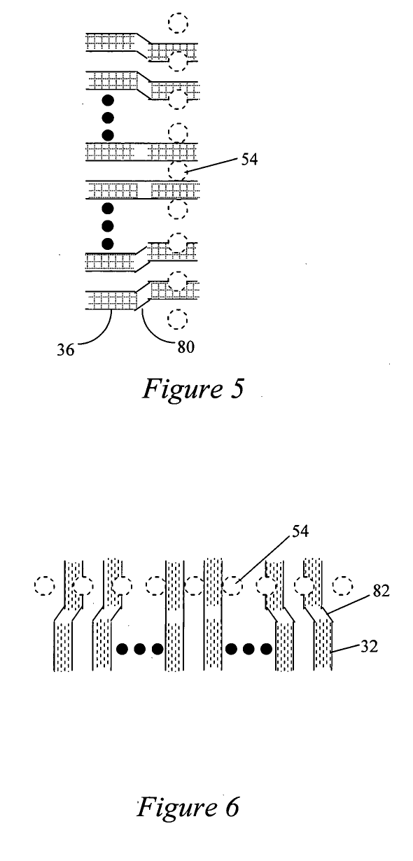

FIG. 5 shows conductive traces 36 that connect the row decoder (not shown) with the pixels of the pixel array. The traces at the center of the array may be a straight line. The traces at the outer portions of the area may have a bend 80. The bend 80 shifts the location of the conductive traces so that light travels onto the photodiodes 54 without obstruction by the traces. The bends 80 vary the pitch of the conductive traces. In general, the pitch is varied to prevent trace obstruction of the light.

FIG. 6 shows conductive traces 32 that connect the light reader with the pixels of the pixel array. The traces at the center of the array may be a straight line. The traces at the outer portions of the area may have a bend 82. The bend 82 shifts the location of the conductive traces so that light travels onto the photo-diodes 54 without obstruction by the traces. The bends 82 vary the pitch of the conductive traces. In general, the pitch is varied to prevent trace obstruction of the light.

While certain exemplary embodiments have been described and shown in the accompanying drawings, it is to be understood that such embodiments are merely illustrative of and not restrictive on the broad invention, and that this invention not be limited to the specific constructions and arrangements shown and described, since various other modifications may occur to those ordinarily skilled in the art.

What is claimed is:

1. An image sensor, comprising:
a pixel array that includes a plurality of pixels;
a row decoder; and,
a plurality of row decoder conductive traces connected to said pixel array and said row decoder, said row decoder conductive traces having a varying pitch.

2. The image sensor of claim 1, wherein said pixel array includes pixels located in a center area of said pixel array and pixels located at an outer area of said pixel array, said row decoder conductive trace pitch varies between said center and outer areas of said pixel array.

3. The image sensor of claim 1, wherein said pixel array and said row decoder are integrated into a single semiconductor die that has a first metal layer, a second metal layer and a third metal layer, said row decoder conductive traces are in said second metal layer.

4. The image sensor of claim 1, further comprising a light reader and a plurality of light reader conductive traces connected to said light reader and said pixel array, said light reader conductive traces have a varying pitch.

5. The image sensor of claim 4, wherein said pixel array includes pixels located in a center area of said pixel array and pixels located at an outer area of said pixel array, said light reader conductive trace pitch varies between said center and outer areas of said pixel array.

6. The image sensor of claim 5, wherein said pixel array and said light reader are integrated into a single semiconductor die that has a first metal layer, a second metal layer and a third metal layer, said light reader decoder conductive traces are in said second metal layer.

7. The image sensor of claim 1, wherein each pixel in said pixel array includes a photodiode.

8. The image sensor of claim 1, wherein said pixel array includes a plurality of micro-lenses.

9. The image sensor of claim 1, wherein some of said row decoder conductive traces have a bend.

10. The image sensor of claim 4, wherein some of said light reader conductive traces have a bend.

11. An image sensor, comprising:
a pixel array that includes a plurality of pixels;
a light reader; and,
a plurality of light reader conductive traces connected to said pixel array and said light reader, said light reader conductive traces having a varying pitch.

12. The image sensor of claim 11, wherein said pixel array includes pixels located in a center area of said pixel array and pixels located at an outer area of said pixel array, said light reader conductive trace pitch varies between said center and outer areas of said pixel array.

13. The image sensor of claim 12, wherein said pixel array and said light reader are integrated into a single semiconductor die that has a first metal layer, a second metal layer and a third metal layer, said light reader conductive traces are in said second metal layer.

14. The image sensor of claim 11, wherein each pixel in said pixel array includes a photodiode.

15. The image sensor of claim 11, wherein said pixel array includes a plurality of micro-lenses.

16. The image sensor of claim 11, wherein some of said light reader conductive traces have a bend.

17. A method for connecting a row decoder to a pixel array of an image sensor, comprising:
routing a plurality of row decoder conductive traces from a row decoder to a pixel array, the row decoder conductive traces having a varying pitch.

18. The method of claim 17, wherein the pitch varies between a center area of the pixel array and an outer area of the pixel array.

19. A method for connecting a light reader to a pixel array of an image sensor, comprising:
routing a plurality of light reader conductive traces from a light reader to a pixel array, the light reader conductive traces having a varying pitch.

20. The method of claim 19, wherein the pitch varies between a center area of the pixel array and an outer area of the pixel array.
